(19) United States
(12) Patent Application Publication
(10) Pub. No.: US 2015/0129112 A1
(43) Pub. Date: May 14, 2015

(54) SHOWER HEAD ASSEMBLY, PLASMA PROCESSING APPARATUS AND METHOD FOR MANUFACTURING A SHOWER HEAD ASSEMBLY

(71) Applicant: Tokyo Electron Limited, Tokyo (JP)

(72) Inventors: Michishige SAITO, Miyagi (JP); Koichi MURAKAMI, Miyagi (JP); Takashi YAMAMOTO, Miyagi (JP)

(21) Appl. No.: 14/528,001

(22) Filed: Oct. 30, 2014

(30) Foreign Application Priority Data
Nov. 12, 2013 (JP) 2013-234110

(51) Int. Cl. H01J 37/32

(52) U.S. Cl. CPC H01J 37/3244; H01J 37/32807
USPC 156/89.12; 156/345.34; 118/723 R; 156/345.27

(57) ABSTRACT

A shower head assembly includes an electrode plate, and a laminate base that is constituted of ceramic sheets and provided to hold the electrode plate. The laminate base includes no bonding surface between the ceramic sheets. The laminate base includes a first gas diffusion space formed in its central area and a second gas diffusion space formed in its peripheral area. A first heater electrode layer is provided above the first gas diffusion space, and a second heater electrode layer is provided above the second gas diffusion space. A first coolant passage is formed above the first gas diffusion space, and a second coolant passage is formed above the second gas diffusion space. A first gas supply passage is connected to the first gas diffusion space, and a second gas supply passage is connected to the second gas diffusion space.

### CROSS-REFERENCE TO RELATED APPLICATIONS

This patent application is based upon and claims the benefit of priority of Japanese Patent Application No. 2013-234110, filed on Nov. 12, 2013, the entire contents of which are incorporated herein by reference.

### BACKGROUND OF THE INVENTION

1. Field of the Invention

The present invention relates to a shower head assembly, a plasma processing apparatus and a method for manufacturing a shower head assembly.

2. Description of the Related Art

In order to perform a desired microfabrication into a substrate, controlling a temperature of the substrate is important. Therefore, as disclosed in Japanese Laid-Open Patent Application Publication No. 2001-160479, implementing a predetermined process on a substrate disposed on a susceptor is performed by controlling a temperature of the susceptor at a desired temperature by using a ceramic heater constituted of a heating element provided in a base of the susceptor and a fluid passage.

In a plasma processing apparatus, a shower head assembly that supplies a gas is sometimes used. In a base of the shower head assembly, a gas diffusion space may be provided to prevent uneven gas supplies. Moreover, a heater element and a fluid passage may be provided in the base to control a temperature of the shower head assembly so as to be an appropriate temperature.

Even in the temperature control of the shower head assembly, when thermal responsiveness or thermal uniformity of the base is excellent, a time period required to reach a target temperature after starting the temperature control of the base can be reduced, and dispersions of in-plane distribution of the temperature and a change of a process characteristic affected by temporal temperature change can be minimized. This serves to implement a preferable plasma process.

However, when embedding the heating element and forming the fluid passage in the shower head assembly, a bonded surface is generated inside the base by a mechanical process, and a thermal resistance present at the bonded surface reduces the thermal responsiveness and the thermal uniformity.

### SUMMARY OF THE INVENTION

Accordingly, in response to the above discussed problems, embodiments of the present invention aim to provide a shower head assembly with preferable thermal responsiveness and thermal uniformity.

According to one embodiment of the present invention, there is provided a shower head assembly that includes an electrode plate, and a laminate base that is constituted of a plurality of ceramic sheets and provided to contact and hold the electrode plate. The laminate base includes no bonding surface between the ceramic sheets. The laminate base includes a first gas diffusion space formed in its central area and a second gas diffusion space formed in its peripheral area. A first heater electrode layer is provided within the laminate base and above the first gas diffusion space, and a second heater electrode layer is provided within the laminate base and above the second gas diffusion space. A first coolant passage is formed above the first gas diffusion space and within the laminate base, and a second coolant passage is formed above the second gas diffusion space and within the laminate base. A first gas supply passage is connected to the first gas diffusion space, and a second gas supply passage is connected to the second gas diffusion space.

According to another embodiment of the present invention, there is provided a plasma processing apparatus that includes a processing chamber, a first electrode having a plate-like shape provided in the processing chamber, and a laminate base constituted of a plurality of ceramic sheets and provided to contact and hold the first electrode. The laminate base includes no bonding surface between the ceramic sheets. The laminate base includes a first gas diffusion space formed in its central area of the laminate base and a second gas diffusion space formed in its peripheral area. A first heater electrode layer is provided within the laminate base and above the first gas diffusion space, and a second heater electrode layer is provided within the laminate base and above the second gas diffusion space. A first coolant passage is formed above the first gas diffusion space and within the laminate base, and a second coolant passage formed above the second gas diffusion space and within the laminate base. A first gas supply passage is connected to the first gas diffusion space, and a second gas supply passage is connected to the second gas diffusion space. A second electrode is provided facing the first electrode. A high frequency power source is provided and configured to supply high frequency power to at least one of the first electrode and the second electrode so as to generate plasma when a plasma gas is supplied from at least one of the first gas supply passage and the second gas supply passage. A control unit is provided and configured to adjust a first temperature in the central area of the laminate ceramic base by controlling the first heater electrode layer and the first coolant passage and a second temperature in the peripheral area of the laminate ceramic base by controlling the second heater electrode layer and the second coolant passage.

According to another embodiment of the present invention, there is provided a method for manufacturing a shower head assembly. In the method, a plurality of ceramic sheets having at least any part of a gas diffusion space, a heater electrode layer, a coolant passage and a gas supply passage is stacked in a predetermined order that can connect the gas supply passage with the gas diffusion space and arrange the heater electrode layer and the coolant passage above the gas diffusion space. Adhesive is applied on contact surfaces of the plurality of ceramic sheets before being stacked. The stacked and integrated ceramic sheets are fired until the adhesive disappears by being dried off. The fired and integrated ceramic sheets are compressed so as to be formed as a laminate.

Additional objects and advantages of the embodiments are set forth in part in the description which follows, and in part will become obvious from the description, or may be learned by practice of the invention. The objects and advantages of the invention will be realized and attained by means of the elements and combinations particularly pointed out in the appended claims. It is to be understood that both the foregoing general description and the following detailed description are exemplary and explanatory and are not restrictive of the invention as claimed.

### BRIEF DESCRIPTION OF THE DRAWINGS

FIG. 1 is a vertical cross-sectional view illustrating a plasma processing apparatus according to an embodiment of the present invention;

FIGS. 2A and 2B are vertical cross-sectional views illustrating a part of a shower head assembly according to an embodiment of the present invention;

FIG. 3 is a diagram for explaining a roll compaction (RC) method used for a method for manufacturing the shower head assembly according to an embodiment of the present invention;

FIG. 4 is an example of a shower head assembly manufactured by using the RC method according to an embodiment of the present invention;

FIG. 5 is an example of a shower head assembly manufactured by using the RC method according to the embodiment of the present invention;

FIG. 6 is an example of a shower head assembly manufactured by using the RC method according to the embodiment of the present invention;

FIG. 7 is an example of a shower head assembly manufactured by using the RC method according to the embodiment of the present invention;

FIG. 8 is an example of a shower head assembly manufactured by using the RC method according to the embodiment of the present invention;

FIG. 9 is an example of a shower head assembly manufactured by using the RC method according to the embodiment of the present invention;

FIG. 10 is an example of a shower head assembly manufactured by using the RC method according to the embodiment of the present invention;

FIG. 11 is an example of a shower head assembly manufactured by using the RC method according to the embodiment of the present invention;

FIG. 12 is an example of a shower head assembly manufactured by using the RC method according to the embodiment of the present invention; and

FIG. 13 is a flowchart illustrating an example of a method for controlling a temperature according to an embodiment of the present invention.

### DETAILED DESCRIPTION OF THE PREFERRED EMBODIMENTS

A description is given below of embodiments of the present invention, with reference to accompanying drawings. Note that elements having substantially the same functions or features may be given the same reference numerals and overlapping descriptions thereof may be omitted.

[Plasma Processing Apparatus]

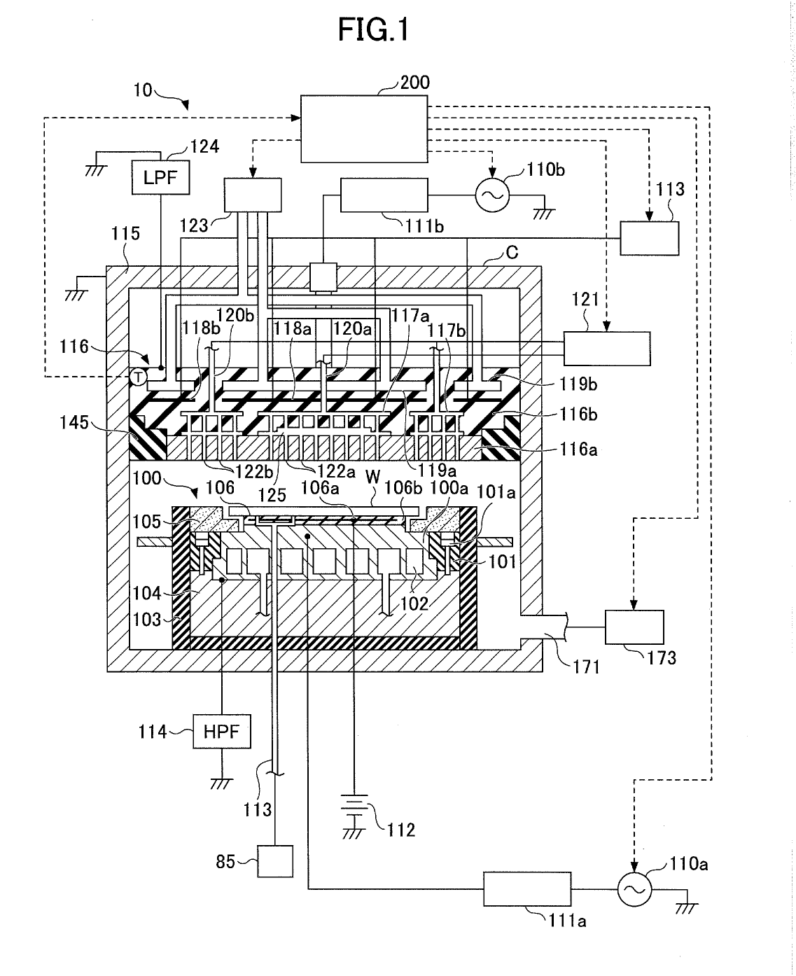

To begin with, a description is given below of an example of a plasma processing apparatus according to an embodiment of the present invention, with reference to FIG. 1. FIG. 1 is a vertical cross-sectional view of the plasma processing apparatus of the embodiment. Here, a description is given below by taking an example of a plasma processing apparatus that applies high frequency power to an upper electrode and a lower electrode in parallel plate electrode plasma processing apparatuses. However, a configuration of the plasma processing apparatus is not limited to this example, but may be any configuration as long as the plasma processing apparatus is configured to apply high frequency power to the upper electrode and the lower electrode.

The plasma processing apparatus 10 includes a chamber C (processing chamber) whose inside is kept airtight and that is electrically grounded. The chamber C has a cylindrical shape, and for example, is made of aluminum and the like having an anodized surface. Inside the chamber C, a susceptor 100 to support a silicon wafer W (hereinafter, just called “wafer W”) is provided. A base 100a of the susceptor 100 is formed of silicon carbide (SiC). The susceptor 100 is held by a support 104. The support 104 is made of aluminum. The susceptor 100 is an example of a second electrode that functions as the lower electrode. On an outer peripheral surface of the susceptor 100, a cylindrical inner wall member 103 made of an insulating material such as quartz is provided, and insulates the susceptor 100 from the chamber C.

A focus ring 105 is provided in an outer periphery on an upper surface of the susceptor 100. The focus ring 105 is made of silicon (Si). An electrostatic chuck 106 is provided on the upper surface of the susceptor 100 to electrostatically attract a wafer W. The electrostatic chuck 106 is structured to include a chuck electrode 106a embedded in an insulating layer 106b. The insulating layer 106b is, for example, made of alumina (Al₂O₃). The chuck electrode 106a is connected to a direct voltage source 112. When a direct voltage is applied to the chuck electrode 106a from the direct voltage source 112, the wafer W is attracted to the electrostatic chuck 106 by a coulomb force.

A fluid passage 102 is formed inside the susceptor 100. A coolant such as Galden (Trademark), coolant water or the like is circulated through the fluid passage 102, thereby adjusting the wafer W to a predetermined temperature. A heat-transfer gas supply source 85 supplies a heat-transfer gas such as helium gas (He), argon gas (Ar) or the like to a back surface of the wafer W on the electrostatic chuck 106 through a gas supply line 113.

A first high frequency power source 100a is connected to the susceptor 100 through a first matching box 111a. The first high frequency power source 110a supplies high frequency power of, for example, 40 MHz to the suceptor 100.

A shower head assembly 116 is provided above the susceptor 100. The shower head assembly 116 is supported by a side wall of the chamber C through an insulating member 145. The shower head assembly 116 is an example of a first electrode that functions as the upper electrode. The shower head assembly and the susceptor 100 forms a pair electrode structure provided opposite to each other.

The shower head assembly includes an electrode plate 116a and a base 116b that supports the electrode plate 116a. A surface opposite to a surface facing the susceptor 100 of the electrode plate 116a is bonded to the base 116b, which supports the electrode plate 116a detachably.

The base 116b is formed of ceramics. In the embodiment, the base 116b is made of silicon carbide (SiC). However, the base 116b is not limited to this, but may be made of any of aluminum nitride (AlN), alumina (Al₂O₃), silicon nitride (SiN), and oxide zirconium (ZrO₂).

A first gas diffusion space 117a is formed on the center side of the base 116b, and a second gas diffusion apace 117b is formed on a peripheral side of the base 116b. A first gas supply passage 120a is coupled to the first gas diffusion space 117a and a second gas supply passage 120b is coupled to the second gas diffusion space 117b. A first gas is diffused in the first gas diffusion space 117a, and introduced to the inside of the chamber C from gas lead-out holes 122a provided in the electrode plate 116a through a plurality of branched first gas supply passages 120a. A gas supply passage 121 supplies a second gas to the second gas supply passage 120b. The second gas is diffused in the second gas diffusion space 117b, and introduced to the inside of the chamber C from gas lead-out holes 122b provided in the electrode plate 116a through a plurality of branched second gas supply passages 120b. This causes the first gas and the second gas to be introduced into a plasma processing space inside the chamber C in a shower form. Here, the first gas and the second gas may be the same gaseous species.

A first heater electrode layer 118a is provided above the first gas diffusion space 117a, and a second heater electrode layer 118b is provided above the second gas diffusion space 117b. The first heater electrode layer 118a and the second heater electrode layer 118b is connected to an alternating current power source 113, heated by power supplied from the alternating current power source 113 and configured to raise a temperature of the base 116b.

A first coolant passage 119a is formed above both of the first gas diffusion space 117a and the first heater electrode layer 118a. A second coolant passage 119b is formed above both of the second gas diffusion space 117b and the second heater electrode layer 118b. The first coolant passage 119a and the second coolant passage 119b are connected to a coolant supply source 123, and are configured to decrease the temperature of the base 116b by allowing the coolant such as Galden (Trademark), water coolant or the like to be circulated through. This causes the wafer W to be adjusted to a predetermined temperature.

The shower head 116 is connected to a second high frequency power source 110b through a second matching box 111b. The second high frequency power source 110b supplies high frequency power, for example, in a range of 2 to 20 MHz, preferably 2 MHz of frequency to the shower head 116.

A low pass filter (LPF) 124 is electrically connected to the shower head 116. The low pass filter 124 is to cut off the high frequency power in a higher frequency range from the second high frequency power source 110b and to pass the high frequency power in a lower frequency range from the second high frequency power source 110b. On the other hand, a high pass filter (HPF) 114 is electrically connected to the susceptor 100. The high pass filter 114 is to cut off the high frequency power in a lower frequency range from the first high frequency power source 110a and to pass the high frequency power in a higher frequency range from the first high frequency power source 110a.

A cylindrical lid body 115 is provided so as to extend upward from the side wall of the chamber C up to a position higher than a height position of the shower head 116. The lid body 115 is a conducting body and grounded. An exhaust port 171 is formed in the bottom side of the chamber C. An exhaust device 173 is connected to the exhaust port 171. The exhaust device 173 includes a vacuum pump (not shown in the drawing), and evacuates the chamber C up to a predetermined degree of vacuum by operating the vacuum pump.

A control unit 200 controls each portion attached to the plasma processing apparatus 10, for example, the gas supply source 121, the exhaust device 171, the high frequency power sources 110a and 110b, the direct voltage source 112 and the transfer-gas supply source 85. The control unit 200 obtains a temperature detected by a temperature measurement part T.

The control unit 200 includes a CPU (Central Processing Unit), a ROM (Read Only Memory) and a RAM (Random Access Memory) that are not shown in the drawing. The CPU performs a plasma process according to a variety of recipes stored in the ROM or the RAM. The recipes specify a process time period, a temperature in the chamber C (including an upper electrode temperature, a side wall temperature of the chamber, an electrostatic chuck temperature and the like), a pressure (gas exhaust pressure), a high frequency power or voltage, various process gas flow rates, a heat-transfer gas flow rate and the like that are control information of the plasma processing apparatus in response to process conditions.

This causes a plasma process to be performed according to the recipe, and the plasma process such as an etching process and the like is performed on a wafer Won the susceptor 100 under conditions that the suceptor 100 and the shower head 116 are controlled so as to become desired temperatures. At this time, the temperature on the center side of the shower head 116 is adjusted by the first heater electrode layer 118a and the first coolant passage 119a. Moreover, the temperature on the peripheral side of the shower head 116 is adjusted by the second heater electrode layer 118b and the second coolant passage 119b.

[Configuration of Shower Head Assembly]

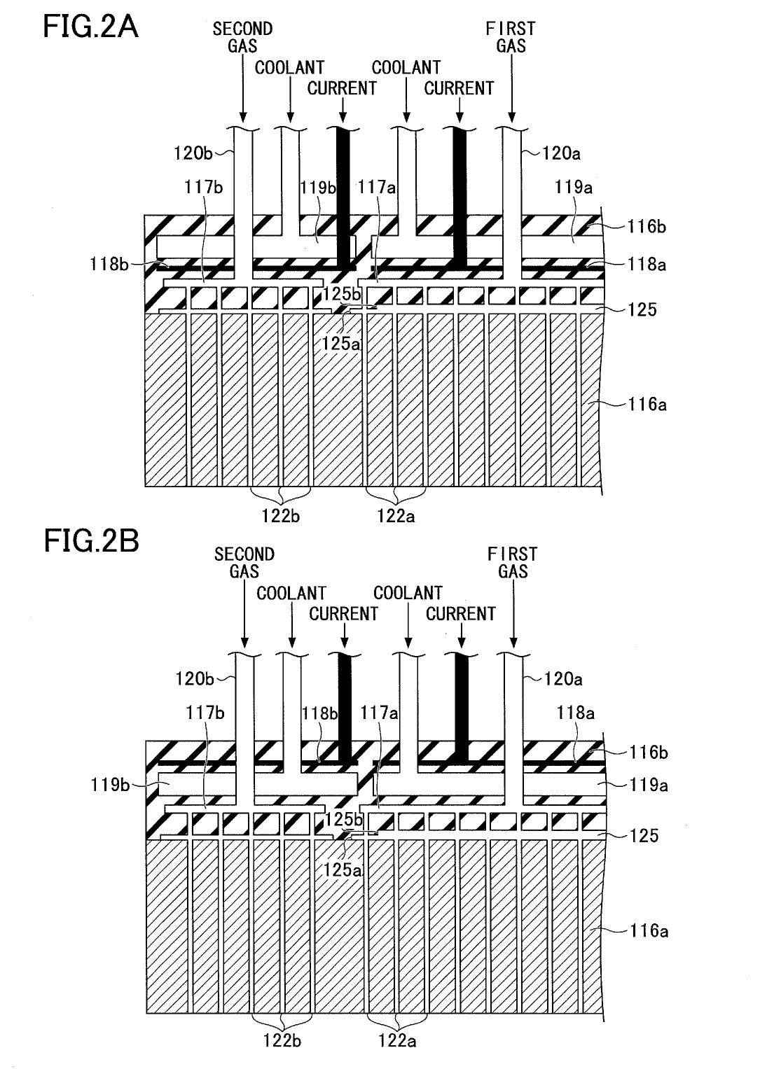

The shower head assembly 116 includes a dielectric part having different heights between the center portion and the peripheral portion, arranged on the back surface of the electrode plate 116a (the surface opposite to the susceptor 100 side). A description is given below of a detailed configuration of the shower head assembly 116 including the dielectric parts, with reference to FIGS. 2A and 2B. FIGS. 2A and 2B are diagrams enlarging a part of the shower head assembly 116 in FIG. 1.

The first gas is introduced into the center side of the chamber C from the gas lead-out holes 122a by way of the first gas supply passage 120a and the first gas diffusion space 117a formed in the center side. The first heater electrode layer 118a and the first coolant passage 119a provided at an upper position of the first gas diffusion space 117a control the temperature on the center side of the shower head assembly 116.

Furthermore, in the embodiment, the second gas is introduced into the peripheral side in the chamber C from the gas lead-out holes 122b by way of the second gas supply passage 120b and the second gas diffusion space 117b formed in the peripheral side. The second heater electrode layer 118b and the second coolant passage 119b provided at an upper position of the second gas diffusion space 117b control the temperature on the peripheral side of the shower head assembly 116. The shower head assembly 116 of the embodiment is divided into two zones of the center side and the peripheral side, and such a configuration makes it possible to supply a gas to each of the zones and to control the temperature of each of the zones independently.

In the embodiment, a cavity part 125 (relative permittivity equals one) is provided as an example of the dielectric part. The cavity part 125 includes a difference in level so as to increase its height gradually from the peripheral part to the center part. For example, the cavity part 125 may have a shape of stacking two disk-shaped cavity portions 125a and 125b having different diameters from the bottom in the order of having the larger diameter in a concentric fashion. Here, although two of the disk-shaped cavity portions 125a and 125b are stacked, more than two of the disk-shaped cavity portions can be stacked.

A dimension of each of the disk-shaped cavity portions 125a and 125b is determined so that the cavity part 125 functions as a dielectric body having the relative permittivity of one, and generates resonance at the frequency of the high frequency power supplied to the shower head assembly 116 and an electric field perpendicular to the electrode plate 116a in the cavity part 125. In this manner, when the resonance is generated in the cavity part 125 and the electric field perpendicular to the electrode plate 116a is generated, the electric field of the cavity part 125 and the electric field of the electrode plate 116a are combined, and the electric field of the cavity part 125 can control an electric field directly under the cavity part 125 (e.g., from the center to the periphery of the electrode) in the electrode plate 116a.

The dielectric part can be configured by embedding a dielectric member that has the same shape as the cavity part 125 therein. In this case, because the relative permittivity of the dielectric part is determined depending on the relative permittivity of the embedded dielectric member, a dielectric constant of the dielectric part can be set at a desired dielectric constant by selecting the dielectric member. Here, the dielectric member is preferred to have a relative permittivity of 1 to 10. For example, quartz (relative permittivity 3 to 10), alumina, ceramics such as aluminum nitride (relative permittivity 5 to 10), Teflon (Trademark), resin such as polyimide (relative permittivity 2 to 3) can be taken as the dielectric member.

FIG. 2B is a diagram illustrating a modification of the shower head assembly 116. The modification in FIG. 2B differs from the example in FIG. 2A only in that arranged positions of the first and second heater electrode layers 118a and 118b and the first and second coolant passages 119a and 119b are reversed.

More specifically, in the shower head assembly 116 in FIG. 2B, the first coolant passage 119a is formed above the first gas diffusion space 117a and below the first heater electrode layer 118a. Similarly, the second coolant passage 119b is formed above the second gas diffusion space 117b and below the second heater electrode layer 118b. In the case of FIG. 2B, the gas supply and the temperature control for each zone is possible as well as the case of FIG. 2A.

[Method for Manufacturing Shower Head]

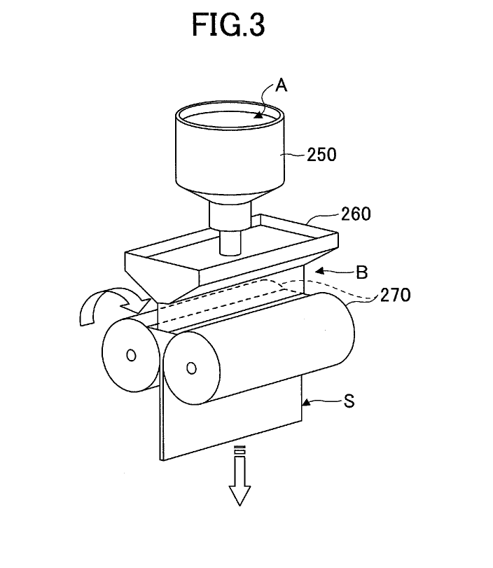

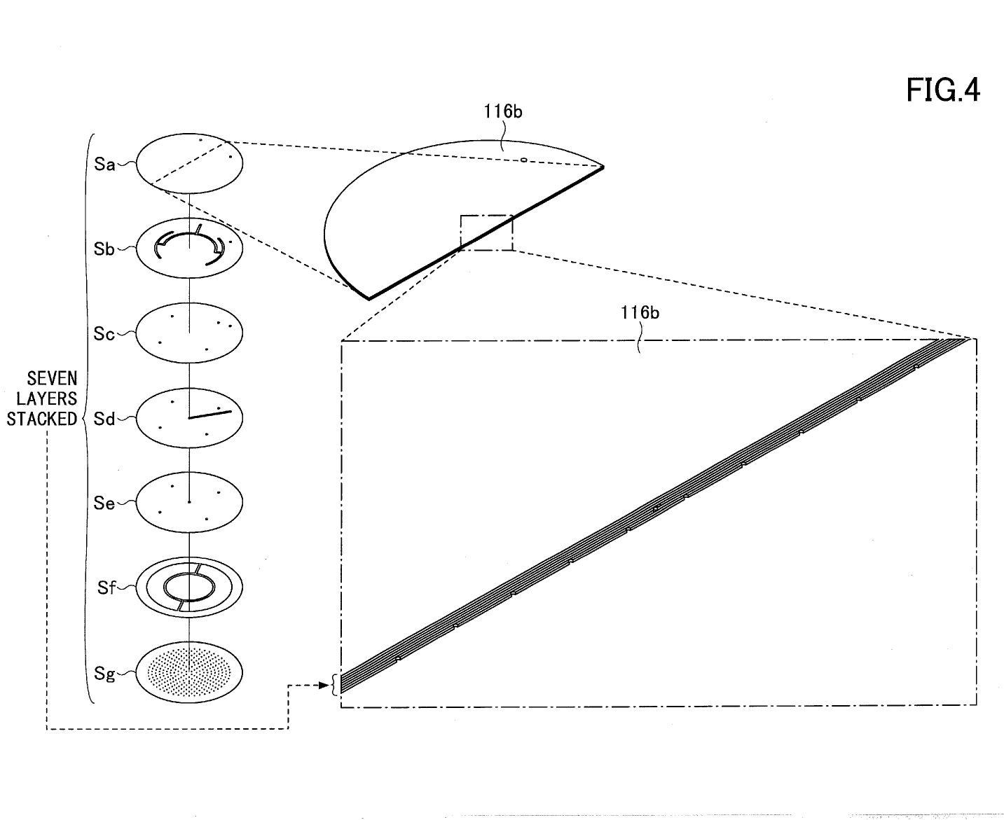

Next, a description is given below of a method for manufacturing the shower head assembly 116 according to an embodiment of the present invention, with reference to FIG. 3. FIG. 3 is a diagram for explaining a roll compaction (RC) method (which is also called just a “RC method” hereinafter) used in manufacturing the shower head assembly 116 according to an embodiment. FIGS. 4 through 12 are diagrams illustrating an example of manufactured shower head assembly 116 according to an embodiment.

In the RC method used in manufacturing the base 116b of the shower head assembly 116 according to the embodiments, powders of silicon (Si) and carbon (C) that are raw materials for manufacturing the base 116b of silicon carbide (hereinafter, expressed as SiC) are input into a container 250 at a desired blend ratio. The container 250 makes slurry A by mixing the input raw materials. The slurry A is ejected from a feeder 260 in a linear fashion (B in FIG. 3), and compressed by two rotating reduction rolls 270, thereby forming a ceramic sheet S made of SiC (a sheet of ceramics).

The ceramic sheet of SiC is formed into a desired shape by laser beam machining. For example, FIGS. 4 through 11 illustrate seven laser-processed ceramic sheets Sa through Sg, respectively. The base 116b is manufactured by stacking, firing and compressing seven of the ceramic sheets Sa through Sg.

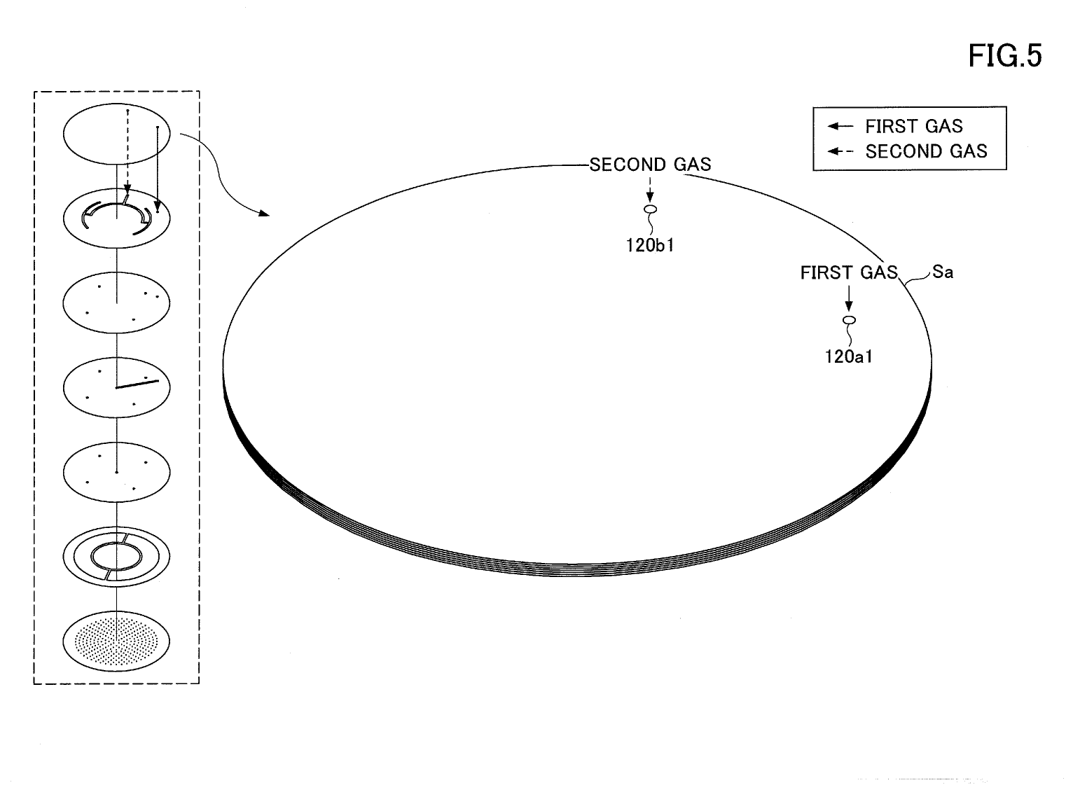

A ceramic sheet Sa illustrated in FIG. 5 is a first layer (top sheet), and has a gas lead-in openings 120a1 and 120b1 formed therein. More specifically, a first gas lead-in opening 120a1 to introduce the first gas thereto and a second gas lead-in opening 120b1 to introduce the second gas thereto are formed in the ceramic sheet Sa.

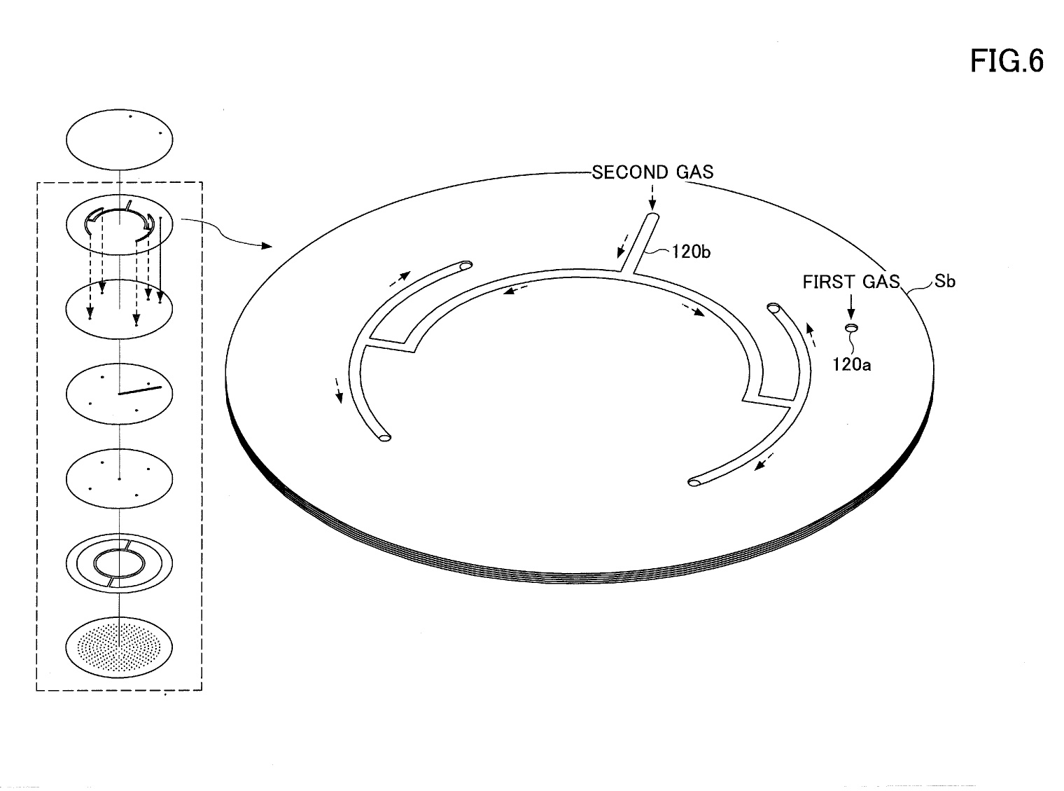

A ceramic sheet Sb illustrated in FIG. 6 is a second layer, and mainly has the gas supply passage 120b to let the second gas flow formed therein. The ceramic sheet Sb has a thickness to allow the second gas supply passage to be formed therein. The second gas supply passage 120b has a pathway that divides into four branches so as to be formed at positions where the gas lead-in hole is divided into quarters. This enables a gas to be supplied into the approximately ring-shaped second gas diffusion space 117b provided on the peripheral side from four locations. When a gas supply hole connected to the second gas diffusion space 117b is a single hole, because the second gas diffusion space 117b is a narrow buffer space, unevenness of pressure is generated inside the buffer space due to poor (low) conductance, which prevents the gas from being supplied uniformly. In contrast, by supplying the second gas from the four locations to the second gas diffusion space 117b, the pressure inside the diffusion space 117b becomes uniform, and a flow rate of the gas supplied to the inside is less likely to deviate.

Thus, in the ceramic sheet Sb, a complicated gas pathway can be formed by the laser beam machining. Here, a cross section of the first gas supply passage 120a to let the first gas flow is formed in the ceramic sheet Sb.

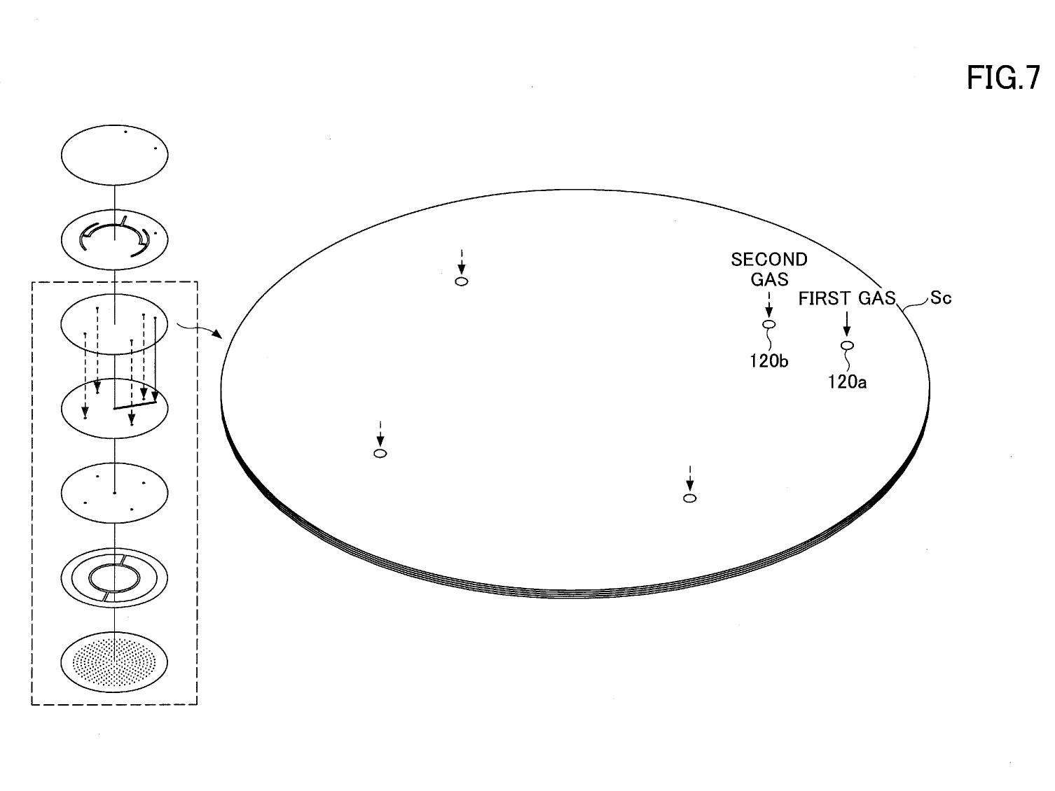

A ceramic sheet Sc illustrated in FIG. 7 is a third layer, and a cross-sectional hole of the single first gas supply passage 120a to let the first gas flow and four cross-sectional holes of the second gas supply passage 120b to let the second gas flow are formed in the ceramic sheet Sc.

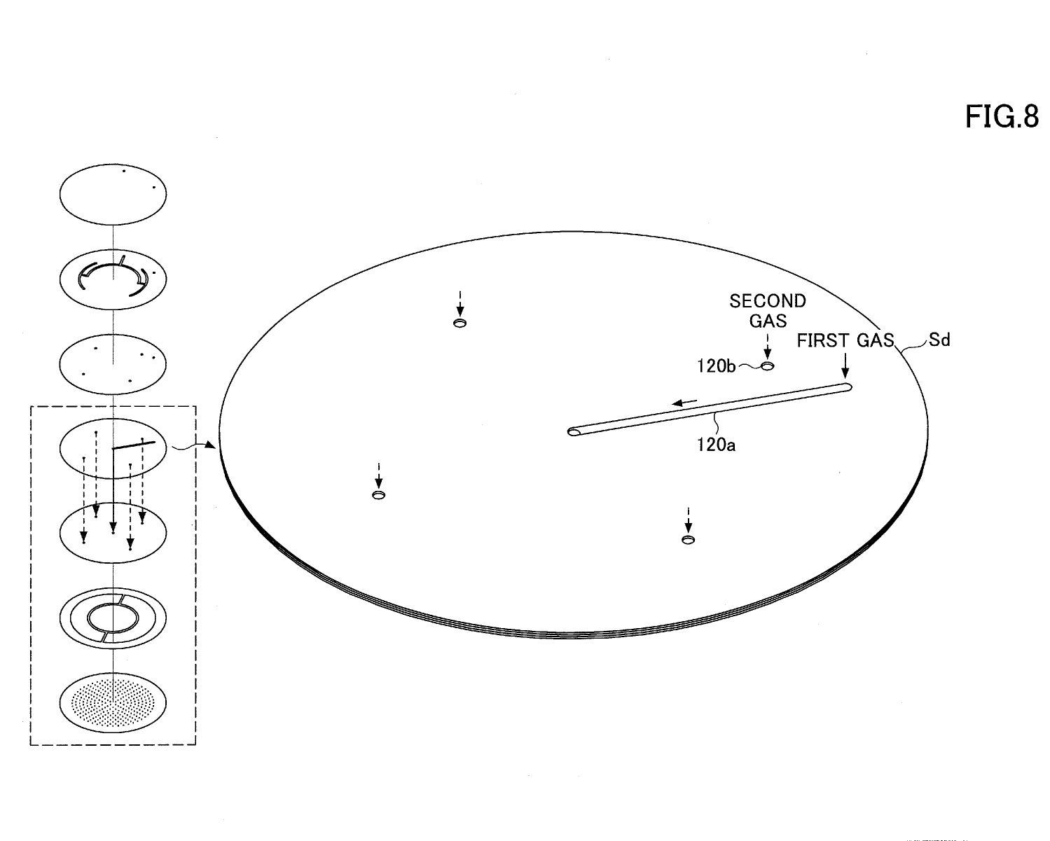

A ceramic sheet Sd illustrated in FIG. 8 is a fourth layer, and the first gas supply passage 120a to let the first gas flow is mainly formed in the ceramic sheet Sd. The ceramic sheet Sd has a thickness that allows the first gas supply passage 120a to be formed therein. The first gas supply passage 120a has a route to let the first gas flow to a portion of the first gas supply passage 120a located at the center of the ceramic sheet Sd so as to supply the first gas diffusion space 117a provided on the center side of the base 116b. Here, four cross-sectional holes of the second gas supply passage 120b to let the second gas flow are formed in the ceramic sheet Sd.

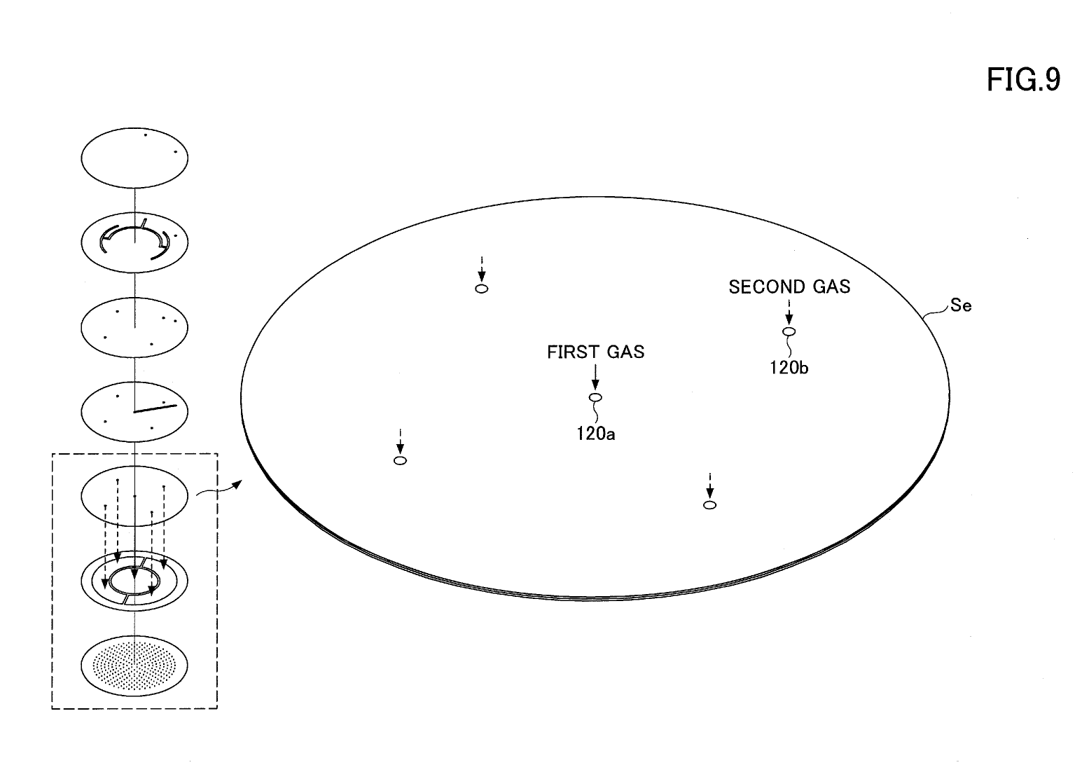

A ceramic sheet Se illustrated in FIG. 9 is a fifth layer, and a cross-sectional hole of the first gas supply passage 120a to let the first gas flow and four cross-sectional holes of the second gas supply passage 120b to let the second gas flow are formed in the ceramic sheet Se.

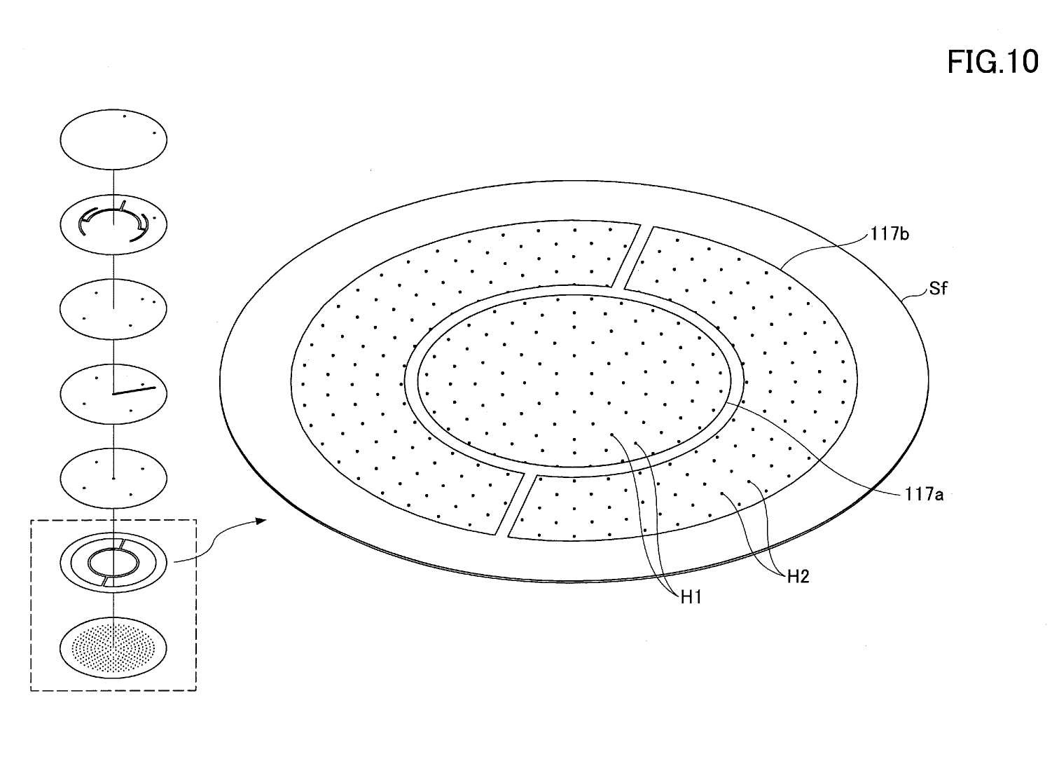

A ceramic sheet Sf illustrated in FIG. 10 is a sixth layer, and has the first gas diffusion space 117a that diffuses the first gas and is communicated with the first gas supply passage 120a and the second gas diffusion space 117b that diffuses the second gas and is communicated with the second gas supply passage 120b formed therein. In the bottom surface of the first gas diffusion space 117a and the second gas diffusion space 117b, many gas holes H1 to introduce the first gas to the chamber C side and gas holes H2 to introduce the second gas to the chamber C side are uniformly formed.

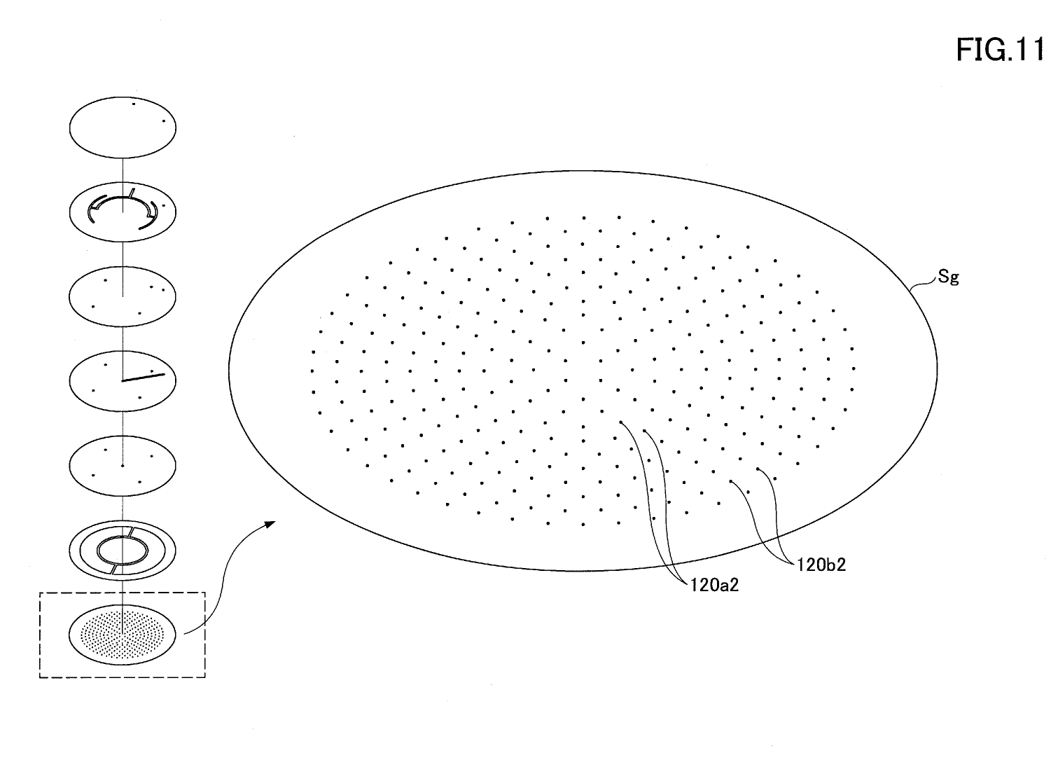

A ceramic sheet Sg illustrated in FIG. 11 is a seventh layer, and the first gas lead-out openings 120a2 and the second gas lead-out openings 120b2 are arranged uniformly in the ceramic sheet Sg. This causes the first gas to be supplied to the center side of the wafer W in a shower fashion from the first gas lead-in openings 120a2 and causes the second gas to be supplied to the peripheral side of the wafer W in a shower fashion from the second gas lead-in openings 120b2.

<Firing and Compression>

The ceramic sheets Sa through Sg are input into a processing furnace in a state of an adhesive applied therebetween and stacked thereon in series, and then fired and compressed. The base 116b of the shower head assembly 116 according to the embodiment can be fired rapidly because the base 116b is not made of a bulk material but has a laminated structure of thin ceramic sheet materials, which can reduce operating time of the processing furnace. Moreover, because particles are combined by solid phase sintering, strength of a base made of SiC is equal to or more than that of the bulk material.

The adhesive between layers of the ceramic sheets Sa through Sg disappears in firing. This produces the base 116b of the shower head assembly 116 according to the embodiment without a bonding surface thereinside. In other words, the base 116b of the shower head assembly 116 can form a hollow structure such as the gas supply passages and the like thereinside without having the bonding surface by integral firing. This removes a thermal resistance between the layers of the ceramic sheets Sa through Sg, and can manufacture the shower head assembly 116 having high thermal responsiveness and excellent uniform responsiveness. In addition, because structures such as the gas supply passages inside the base 116b are formed by the laser beam machining, a variety of shapes can be flexibly formed.

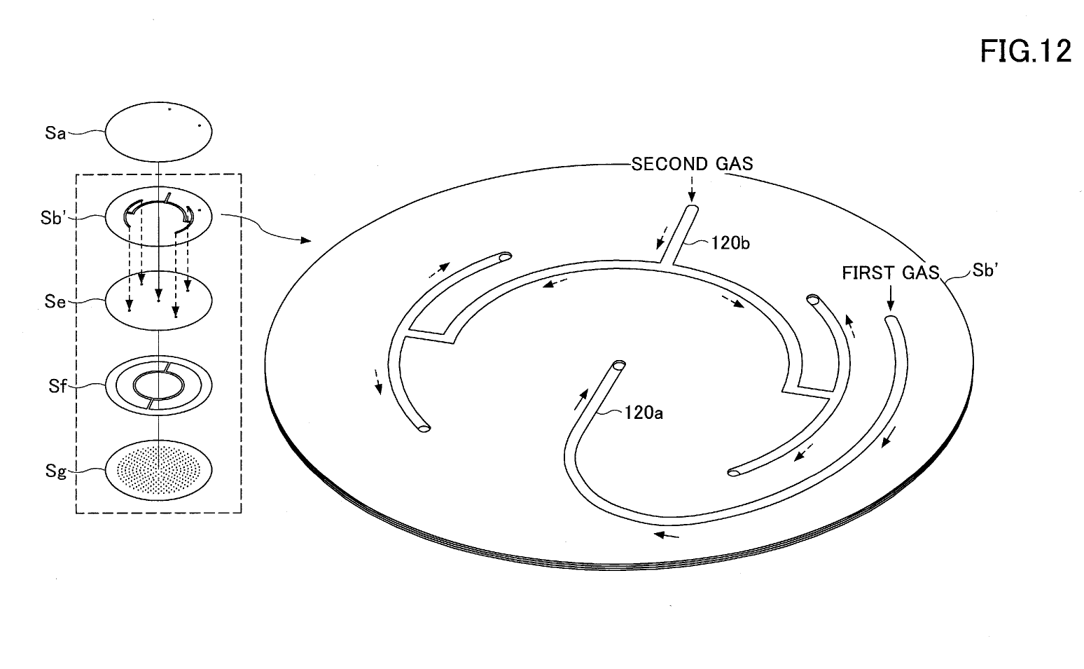

For example, in the above embodiments, the description is given by taking the example of forming the second gas supply passage 120b in the ceramic sheet Sb in FIG. 6 and forming the first gas supply passage 120a in the ceramic sheet Sd in FIG. 8. However, as illustrated in FIG. 12, the first gas supply passage 120a and the second gas supply passage 120b may be formed in a single sheet of ceramic sheet Sb′.

Moreover, in the above embodiments, the description is given of the first and second gas diffusion spaces 117a and 117b and the first and second gas supply passages 120a and 120b formed into the ceramic sheets Sa through Sg by using FIGS. 4 through 11. However, the first heater electrode layer 118a and the second heater electrode 118b can be also embedded in any positions in any of the sheets Sa through Sg of the stacked ceramic sheet S, and can be laminated. The first coolant passage 119a and the second coolant passage 119b can be also formed in any positions in any of the sheets Sa through Sg of the ceramic sheet S, and can be laminated.

This enables the base 116b to be manufactured having the first and second gas diffusion spaces 117a and 117b, the first and second heater electrode layers 118a and 118b, the first and second coolant passages 119a and 119b, and the first and second gas supply passages 120a and 120b formed therein and without a bonding surface.

Moreover, according to the method for manufacturing the shower head assembly 116 using the RC method, any numbers of gas lead-in openings 120a1 and 120b1 and gas lead-out openings 120b1 and 120b2 can be formed in any positions. When the gas lead-in openings 120a1, 120b1 and the gas lead-out openings 120a2, 120b2 of the shower head assembly 116 are in the same straight lines, respectively, because the gas routes cannot be long, preventing an abnormal electric discharge is difficult.

Therefore, the first gas supply passage 120a connects the first gas lead-in opening 120a1 to let in the first gas with the first gas lead-out openings 120a2 to let out the first gas by way of the first gas diffusion space 117a, and is formed by being bypassed so as not to arrange the first gas lead-in opening 120a1 and the first gas lead-out openings 120a2 in the same straight line.

Furthermore, the second gas supply passage 120b connects the second gas lead-in opening 120b1 to let in the second gas with the second gas lead-out openings 120b2 to let out the second gas by way of the second gas diffusion space 117b, and is formed by being bypassed so as not to arrange the second gas lead-in opening 120b1 and the second gas lead-out openings 120b2 in the same straight line. This can prevent an abnormal electric discharge in the shower head assembly 116.

[Method for Controlling Temperature]

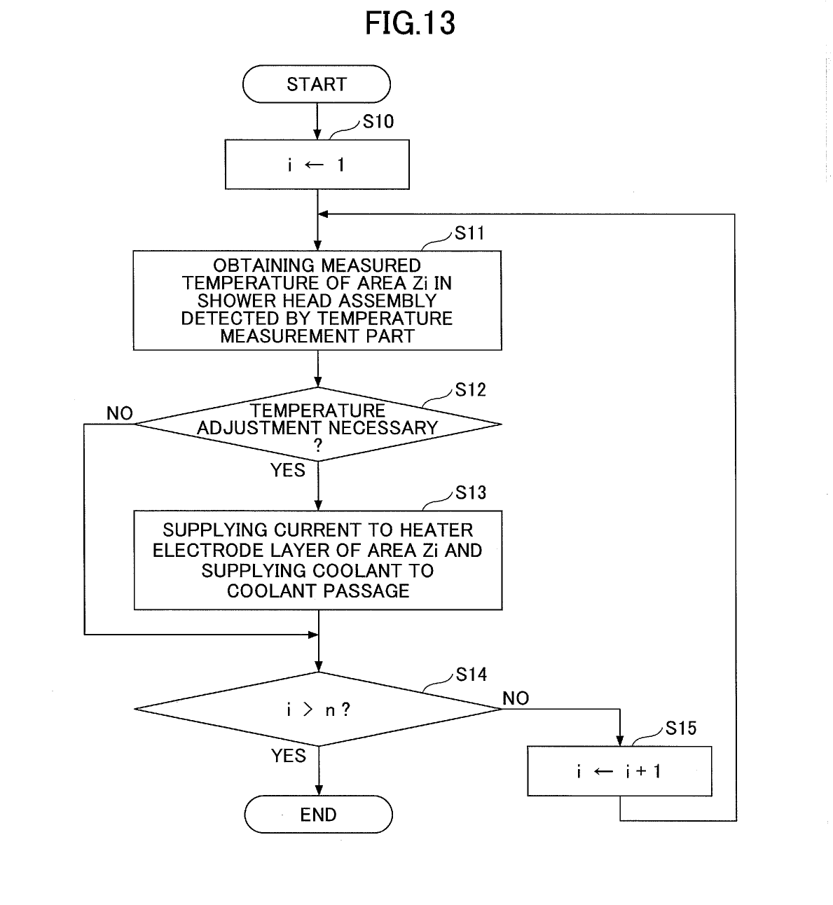

Finally, a brief description is given of a method for controlling a temperature of the shower head assembly 116. FIG. 13 is a flowchart illustrating an example of the method for controlling a temperature according to an embodiment. When dividing the shower head assembly 116 into two zones Z₁ and Z₂ of the center side and the peripheral side, as described below, each zone Zᵢ is independently controlled by the control unit 200.

When a process of controlling the temperature in FIG. 13 starts, to begin with, a value of “1” is assigned to the variable “i” indicating the zone of a temperature control object (step S10). Next, the control unit 200 obtains a temperature detected by the temperature measurement part T (step S11). The temperature measurement part T may have any configuration as long as the temperature measurement part T has a function of detecting a temperature of each of the zones Z₁ and Z₂. For example, the temperature measurement part T may be a thermocouple or a temperature sensor provided in each of the zones Z₁ and Z₂ or a predetermined position of the shower head assembly 116.

Next, the control unit 200 determines whether or not temperature adjustment is needed based on a difference between a measured temperature and a setting temperature (target temperature) (step S12). When it is determined that the temperature adjustment is not needed, the process goes to step S14.

In contrast, when it is determined that the temperature adjustment is needed, the control unit 200 controls the temperature of the zone Z₁ so as to become a predetermined temperature by using the first heater electrode layer 118a and the first coolant passage 119a built in the zone Z₁.

Subsequently, the control unit 200 determines whether or not the variable i is larger than the zone number n (=2) (step S14). When the variable “i” is equal to or smaller than the zone number “2”, a value of “1” is added to the variable “i” (step S15), and the process returns to step S11. The control unit 200 performs the temperature control of the next zone Z₂ by implementing steps S11 through S14.

In step S11, the control unit 200 obtains the temperature detected by the temperature measurement part T, and when determining that the temperature adjustment is not needed in step S12, the process moves to step S14. On the other hand, when determining that the temperature adjustment is needed, the control unit 200 controls the temperature of the zone Z₂ so as to become a predetermined temperature by the current supply to the second heater electrode layer 118b and the coolant supply to the second coolant passage 119b.

When the variable “i” is greater than the zone number “2”, the control unit 200 determines that the temperature adjustment of the zones Z₁ and Z₂ are completed, and ends the process of controlling the temperature.

As discussed above, although the description is given of the shower head assembly 116 and the plasma processing apparatus according to the embodiments, the present invention is not limited to the above embodiments, and the present invention includes all such variations and modifications that may be made without departing from the scope of the present invention.

For example, in the above embodiments, although the RC method is illustrated as the method for manufacturing the shower head assembly 116, the present invention is not limited to the embodiments. For example, the shower head assembly 116 can be manufactured by a doctor blade method and the like by using a ceramic sheet.

Moreover, for example, in the above embodiments, the description is given of the shower head 116 that supplies the gases to the divided two zones and can control the temperatures of the two zones. However, the internal structure of the shower head 116 is not limited to the embodiments, and the internal structure of the base 116b may be changed to be able to divide three zones, four zones or more zones and to control the divided zones.

Furthermore, a plurality of pairs of the first and second heater electrode layers 118a and 118b and the first and second coolant passages 119a and 119b may be stacked vertically. In addition, one of the first and second heater electrode layers 118a and 118b may be made a single layer, and the other may be made multiple layers. This makes it possible to control the temperature so as to positively have uneven temperature distribution.

The shower head assembly 116 according to the embodiments of the present invention can be applied to a general plasma processing apparatus. For example, the shower head assembly 116 according to the embodiments of the present invention can be applied to an etching apparatus, a chemical vapor deposition (CVD) apparatus, an ashing processing apparatus, and a film deposition apparatus or the like. On this occasion, a capacitively coupled plasma (CCP) generation unit, an inductively coupled plasma (ICP) generation unit, a helicon wave plasma (HWP) generation unit, a microwave excitation surface wave plasma generation unit including microwave plasma generated from a radial line slot antenna or slot plane antenna (SPA) plasma, and an electron cyclotron resonance (ECR) plasma generation unit using the above plasma generation unit can be used as a plasma generation unit to generate plasma in the plasma processing apparatus. In addition, the shower head assembly 116 according to the embodiments of the present invention can be applied to a substrate processing apparatus that processes a substrate by means other than plasma.

The object to be processed in the embodiments of the present invention is not limited to the (semiconductor) wafer used in the description of the embodiments, but for example, may be a large substrate for a flat panel display, a substrate for an EL (electroluminescence) device or a solar cell.

As described above, according to the embodiments of the present invention, a shower head assembly having excellent thermal responsiveness and thermal uniformity can be provided.

Here, the present invention is not limited to the configuration illustrated in the embodiments, but combining the configurations cited in the above embodiments with another component and the like are possible. In this regards, numerous variations and modifications are possible without departing from the scope of the present invention, and may be appropriately determined depending on such variations and modifications that may be made.

What is claimed is:

1. A shower head assembly comprising:
an electrode plate;
a laminate base constituted of a plurality of ceramic sheets and provided to contact and hold the electrode plate, the laminate base including no bonding surface between the ceramic sheets;
a first gas diffusion space formed in a central area of the laminate base;
a second gas diffusion space formed in a peripheral area of the laminate base;
a first heater electrode layer provided within the laminate base and above the first gas diffusion space;
a second heater electrode layer provided within the laminate base and above the second gas diffusion space;
a first coolant passage formed above the first gas diffusion space and within the laminate base;
a second coolant passage formed above the second gas diffusion space and within the laminate base;
a first gas supply passage connected to the first gas diffusion space; and
a second gas supply passage connected to the second gas diffusion space.

2. The shower head assembly as claimed in claim 1, wherein the plurality of ceramic sheets include at least any part of the first gas diffusion space, the second gas diffusion space, the first heater electrode layer, the second heater electrode layer, the first coolant passage, the second coolant passage, the first gas supply passage and the second gas supply passage formed therein, and the laminate ceramic base is formed by stacking, firing and compressing the plurality of ceramic sheets.

3. The shower head assembly as claimed in claim 1, further comprising:
a dielectric part provided on a surface of the electrode plate on the laminate ceramic base side, the dielectric part having heights in its central portion and peripheral portion different from each other.

4. The shower head assembly as claimed in claim 3, wherein the dielectric part is formed as a cavity part.

5. The shower head assembly as claimed in claim 3, wherein the dielectric part is filled with a dielectric material.

6. The shower head assembly as claimed in claim 1,
wherein the first gas supply passage includes a first gas lead-in opening at an upper end thereof and a first gas lead-out opening at a lower end thereof and is formed to connect the first gas led-in opening with the first gas lead-out opening by way of the first gas diffusion space by being bypassed so as not to arrange the first gas lead-in opening and the first gas lead-out opening in a same straight line, and
the second gas supply passage includes a second gas lead-in opening at an upper end thereof and a second gas lead-out opening at a lower end thereof and is formed to connect the second gas led-in opening with the second gas lead-out opening by way of the second gas diffusion space by being bypassed so as not to arrange the second gas lead-in opening and the second gas lead-out opening in a same straight line.

7. The shower head assembly as claimed in claim 1, wherein the laminate ceramic base is made of any one of silicon carbide, aluminum nitride, alumina, silicon nitride and zirconium oxide.

8. A plasma processing apparatus comprising:
a processing chamber;
a first electrode having a plate-like shape provided in the processing chamber;
a laminate base constituted of a plurality of ceramic sheets and provided to contact and hold the first electrode, the laminate base including no bonding surface between the plurality of ceramic sheets;
a first gas diffusion space formed in a central area of the laminate base;
a second gas diffusion space formed in a peripheral area of the laminate base;
a first heater electrode layer provided within the laminate base and above the first gas diffusion space;
a second heater electrode layer provided within the laminate base and above the second gas diffusion space;
a first coolant passage formed above the first gas diffusion space and within the laminate base;
a second coolant passage formed above the second gas diffusion space and within the laminate base;
a first gas supply passage connected to the first gas diffusion space;
a second gas supply passage connected to the second gas diffusion space;
a second electrode provided facing the first electrode;
a high frequency power source configured to supply high frequency power to at least one of the first electrode and the second electrode so as to generate plasma when a plasma gas is supplied from at least one of the first gas supply passage and the second gas supply passage; and
a control unit configured to adjust a first temperature in the central area of the laminate ceramic base by controlling the first heater electrode layer and the first coolant passage and a second temperature in the peripheral area of the laminate ceramic base by controlling the second heater electrode layer and the second coolant passage.

9. A method for manufacturing a shower head assembly, the method comprising:
stacking a plurality of ceramic sheets having at least any part of a gas diffusion space, a heater electrode layer, a coolant passage and a gas supply passage in a predetermined order that can connect the gas supply passage with the gas diffusion space and arrange the heater electrode layer and the coolant passage above the gas diffusion space, adhesive being applied on contact surfaces of the plurality of ceramic sheets before being stacked;
firing the stacked and integrated ceramic sheets until the adhesive disappears by being dried off; and
compressing the fired and integrated ceramic sheets so as to be formed as a laminate.

10. The method as claimed in claim 9, further comprising:
forming a plurality of planar ceramic sheets by using a roll compaction method;
forming any part of the gas diffusion space, the heater electrode layer, the coolant passage and the gas supply passage into each of the plurality of planar ceramic sheets by laser beam machining.

11. The method as claimed in claim 10, wherein the diffusion space, the heater electrode layer, the coolant passage and the gas supply passage are formed separately in each of a central area and a peripheral area of the plurality of planar ceramic sheets.
